(19) United States
(12) Patent Application Publication
(10) Pub. No.: US 2003/0062562 A1
(43) Pub. Date: Apr. 3, 2003

(54) Method for fabricating gate oxides in surrounding gate DRAM concepts

(76) Inventors: Bernd Goebel, Dresden (DE); Peter Moll, Dresden (DE); Harald Seidl, Feldkirchen (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/247,967

(22) Filed: Sep. 20, 2002

(30) Foreign Application Priority Data
Sep. 20, 2001 (EP) 01 122 468.0

(51) Int. Cl. H01L 27/108

(52) U.S. Cl. 257/302; 257/296

(57) ABSTRACT

The invention relates to a vertical transistor for a DRAM memory cell, in which a deposited layer is used as a gate insulator, and this deposited layer simultaneously serves for electrical insulation between the transistor and a storage capacitor.

### BACKGROUND OF THE INVENTION

### Field of the Invention

The present invention relates to a DRAM (dynamic random access memory) memory cell structure having a vertical transistor.

At the present time, so-called 1-transistor cells are preferably used in dynamic random access memories. As is known, a 1-transistor cell includes a storage capacitor and a selection transistor. One electrode of the capacitor is at a fixed potential, while the other electrode, the so-called storage electrode, is connected to a bit line via the source-drain path of the selection transistor. The gate electrode of the selection transistor is driven via a word line. For space reasons, the storage capacitor is often formed as a so-called trench capacitor. In the case of such a trench capacitor, a hole is etched into a substrate, in particular a semiconductor or silicon substrate. A dielectric and also a storage electrode are introduced into this hole. The storage capacitor electrode that is held at the fixed potential is formed by a highly doped region located in the silicon substrate.

At the present time, the selection transistor is usually provided on the planar surface of the substrate beside the storage capacitor. A memory cell constructed in this way requires at least an area of 8 F², where F denotes the minimum feature size in the lithography.

Hitherto, the so-called “folded bit line interconnection” has exclusively been used in the case of DRAMs. This folded bit line interconnection is necessary in order to be able to evaluate small signal levels due to the resultant capacitance equalization.

However, the folded bit line interconnection requires twice the number of word lines to be accommodated on the same cell area of the substrate as in the case without a folded structure.

In order to ensure a cell area of 8 F² when using a folded bit line interconnection, a word line is permitted to have a width of only 1 F. The result of this, however, is that a selection transistor provided in the planar surface of the substrate beside the storage capacitor can have a channel length of at most 1 F.

For future technology generations that provide a minimum feature size F of less than 100 nm, the corresponding selection transistors cannot be expected to satisfy the requirements to be made of them with regard to low leakage currents and performance (corresponds to maximum cell current). Rather, it is feared that high leakage currents and a significant lowering of the performance will result in the case of minimum feature sizes that are significantly below 100 nm.

In order to avoid this problem, concepts have already been proposed in which the channel length of the selection transistor is kept constant. In this case, the selection transistor is embodied in a vertical fashion, that is to say perpendicular to the planar direction, and is arranged above the storage capacitor. However, maintaining a minimum transistor channel length inevitably leads to an ever increasing resistance of the channel, since the ratio of channel length/channel width becomes larger and larger as the minimum feature size decreases.

However, there are already concepts that solve this problem of an ever increasing resistance of the channel of the selection transistor by using a gate enclosing the active region of the selection transistor. In all of these concepts with vertical selection transistors, it is of crucial importance that the gate insulating layer, also called gate oxide hereinafter, can be applied with very good uniformity on the active region of the selection transistor.

Hitherto, thermally produced oxides, in particular, thermally produced silicon dioxide, has exclusively been used as gate oxides for DRAMs. However, the growth rate of thermally produced silicon dioxide has the property that it is dependent on the crystal orientation. Moreover, thermally produced oxides exhibit a significantly reduced growth rate especially at process temperatures below 1000° C. in regions with a high radius of curvature.

Both phenomena, namely the dependence of the growth rate on the crystal orientation, on the one hand, and on the radius Of curvature of the respective region, on the other hand, inevitably bring about an undesired impairment of the uniformity of thermally produced gate oxides and thus also an adverse effect on the performance and reliability of the respective selection transistor.

In order to ensure adequate electrical isolation between a vertical selection transistor and the storage capacitor located below the selection transistor, when using prior art thermal oxides, adequate electrical insulation must be insured between the selection transistor and the storage capacitor. At the present time, this is done by depositing a so-called trench top oxide (TTO), which is provided between the storage capacitor and the selection transistor in the trench, and which requires a separate fabrication step.

### SUMMARY OF THE INVENTION

It is accordingly an object of the invention to provide a DRAM memory cell structure with a vertical transistor and a method for producing the DRAM memory cell structure which overcomes the above-mentioned disadvantages of the prior art apparatus and methods of this general type.

In particular, it is an object of the invention to provide a vertical transistor for use in a DRAM memory cell, such that the transistor is distinguished by good performance with high reliability.

With the foregoing and other objects in view there is provided, in accordance with the invention, a DRAM memory cell structure including: semiconductor material formed with a trench having a sidewall and a bottom region; a storage capacitor provided in the bottom region of the trench; a vertical transistor configured in the sidewall of the trench and configured above the storage capacitor; and a deposited dielectric layer forming a first insulating layer isolating the transistor from the storage capacitor. The dielectric layer also forms a second insulating layer serving as a gate insulator of the transistor.

In the inventive vertical transistor, a deposited dielectric layer is used as the gate oxide. This dielectric layer may be fabricated by ALD (atomic layer deposition), also ALCVD, CVD (chemical vapor deposition) or similar methods. An outstanding conformality of the gate oxide will be achieved in any case by these methods. The growth rate in each case is independent of the crystal orientation and curvature of the surface of the substrate.

Moreover, for the dielectric layer, it is possible to use silicon dioxide, as well as other dielectrics with higher dielectric constants, such as, for example, Si₃N₄, Al₂O₃ and similar materials. A deposited dielectric layer for the gate oxide provides the possibility of considerably improving the performance of the selection transistor with unchanged geometry. In particular, it is also possible to produce gate oxides from combinations or a stack of different materials, such as, for example, SiO₂/SiN, SiO₂/Al₂O₃/SiO₂, etc.

Preferred layer thicknesses of the dielectric layer lie between 2 and 20 nm. However, smaller or larger thicknesses are also possible.

Finally, using a deposited dielectric layer makes it possible to dispense with the step of depositing a TTO.

What is essential to the present invention, then is the deposition of the gate dielectric for the vertical transistor by using ALD, CVD or similar methods. Furthermore, in the case of the inventive vertical transistor, it is possible to use materials with a higher dielectric constant than silicon dioxide, namely silicon nitride (Si₃N₄), aluminium oxide (Al₂O₃) or similar materials, in order to increase the performance of the selection transistor without increasing the leakage current through the gate dielectric. Finally, the electrical insulation between the selection transistor and the storage capacitor is improved by using a deposited dielectric layer as a gate oxide, so that this electrical insulation is undertaken by the dielectric layer and TTOs can be dispensed with.

Other features which are considered as characteristic for the invention are set forth in the appended claims.

Although the invention is illustrated and described herein as embodied in a method for fabricating gate oxides in surrounding gate DRAM concepts, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1A to 8A are cross sectional views of a vertical transistor after different method steps; and

FIGS. 1B to 8B are plan views that have been rotated through 90° with respect to the views shown in FIGS. 1A to 8A.

### DESCRIPTION OF THE PREFERRED EMBODIMENTS

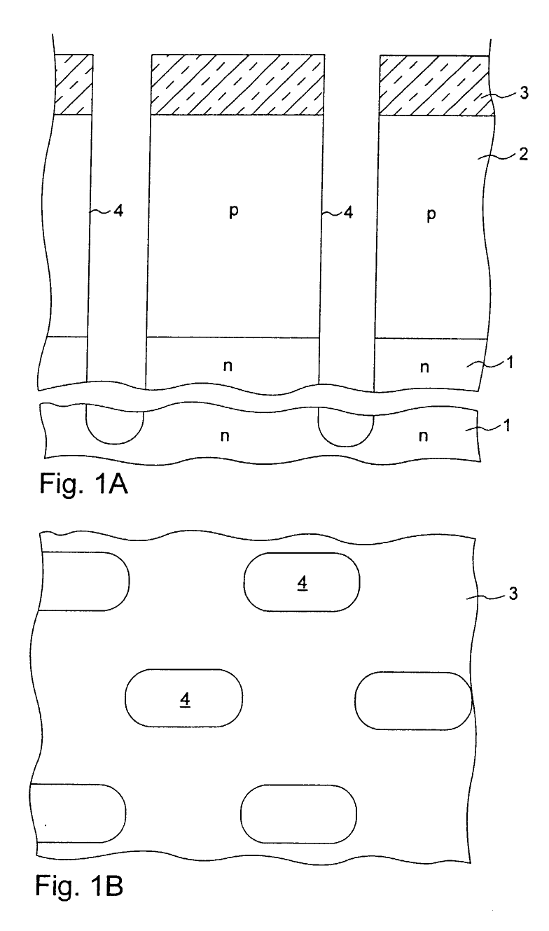

FIGS. 1A to 8A are cross sectional views of a vertical transistor after different method steps have been performed. FIGS. 1B to 8B are plan views that have been rotated through 90° with respect to the views shown in FIGS. 1A to 8A.

Referring now to the figures of the drawing in detail and first, particularly, to FIGS. 1A and 1B thereof, there is shown an n-doped buried plate 1 and a p-doped silicon layer 2. The n-doped buried plate 1 is outdiffused, for example, from arsenic glass in a p-conducting silicon substrate. The p-doped silicon layer 2 is fabricated, for example, by epitaxy on the silicon substrate and is doped with 1×10¹⁵ impurity atoms/cm³, for example. By way of example, boron may be used as the dopant. A silicon nitride layer 3 is additionally provided on this silicon layer 2. Trenches 4 are introduced into the silicon layer 2. The arrangement shown in FIGS. 1A and 1B is fabricated in a customary manner by using individual masking and etching steps.

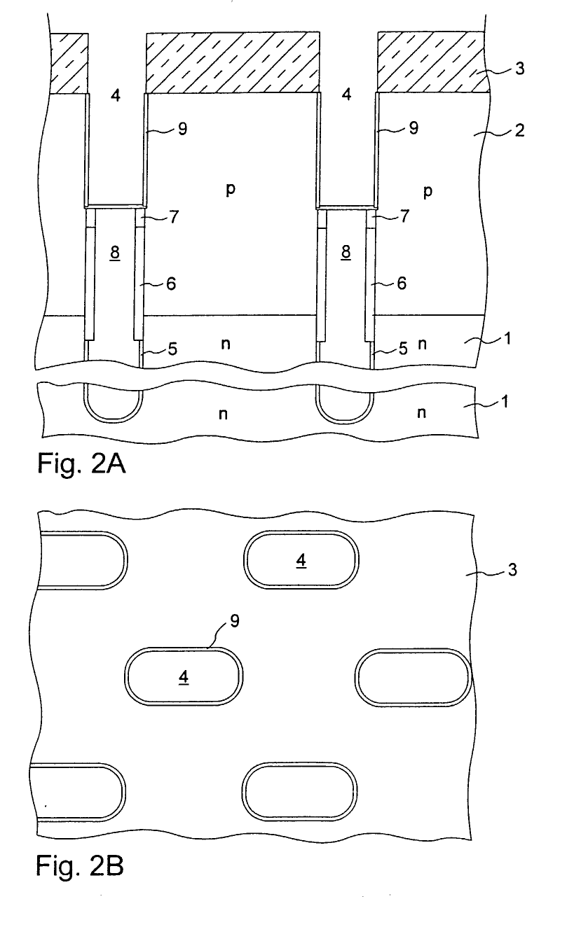

Then, as shown in FIGS. 2A and 2B, the lower edge region of the trenches 4 are filled with an insulating layer 5, for example, made of silicon nitride, a silicon dioxide layer, for example TEOS=tetraethylene orthosilicate 6, and a layer 7 made of undoped amorphous silicon. The inner spaces of the lower edge regions of the trenches are filled with, for example, n-doped polycrystalline silicon 8.

For this purpose, first the insulating layer 5 is produced. Polycrystalline silicon is then deposited, which is n-doped, for example, and may have a layer thickness of 200 nm. This polycrystalline silicon, which later forms the layer 8, is then etched back. The parts of the insulating layer 5 that are uncovered as a result are subsequently etched back using HF, for example. Silicon dioxide (for example TEOS=tetraethylene orthosilicate), which later forms the layer 6, is then deposited with a layer thickness of 20 nm, for example, and is etched anisotropically using CHF₃+O₂, for example, in order to form spacers. Polycrystalline silicon is again deposited, which may be n-doped and has a thickness of 200 nm, for example.

The polycrystalline silicon is subsequently etched back and the layer 6 is then etched back isotropically using HF, for example. Undoped amorphous silicon, which forms the layer 7, is deposited after the etching-back. Finally, there follows a thermal oxidation of the trench sidewalls in order to form a silicon dioxide layer 9 having a thickness of 5 nm, for example. This step can replace the TTO process that is otherwise necessary. The structure shown in FIGS. 2A and 2B is thus present.

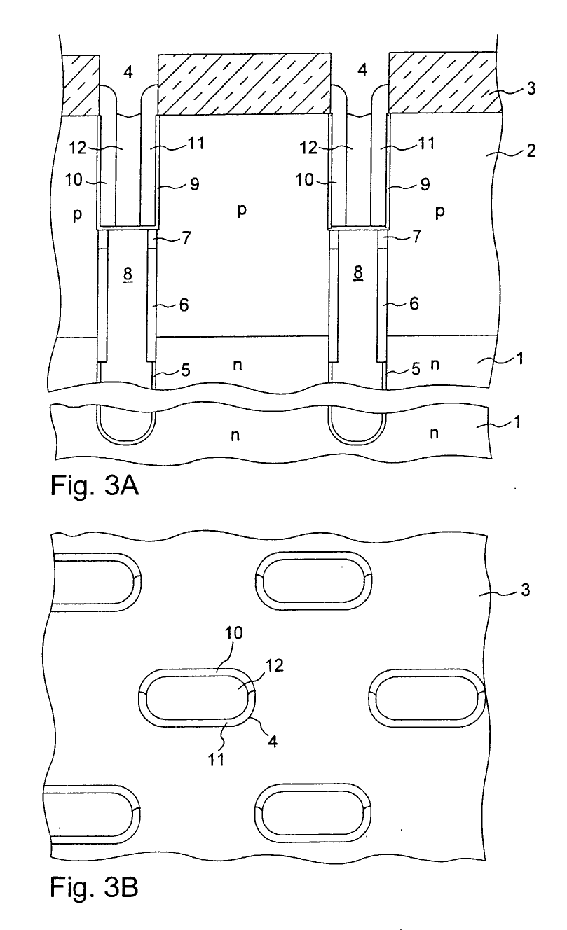

P⁺-doped polycrystalline silicon 10 (if appropriate, an n⁺-type doping can also be chosen instead of a p⁺-type doping) and undoped polycrystalline silicon 11 are then introduced into the remaining trench 4 (cf. FIG. 2A) by deposition and single-sided implantation and etching-back. After the etching-back of this polycrystalline silicon, the upper region of the trench 4 between the doped polycrystalline silicon 10 and the undoped silicon 11 is filled with silicon dioxide 12, which is subsequently etched back. The structure shown in FIGS. 3A and 3B is thus present.

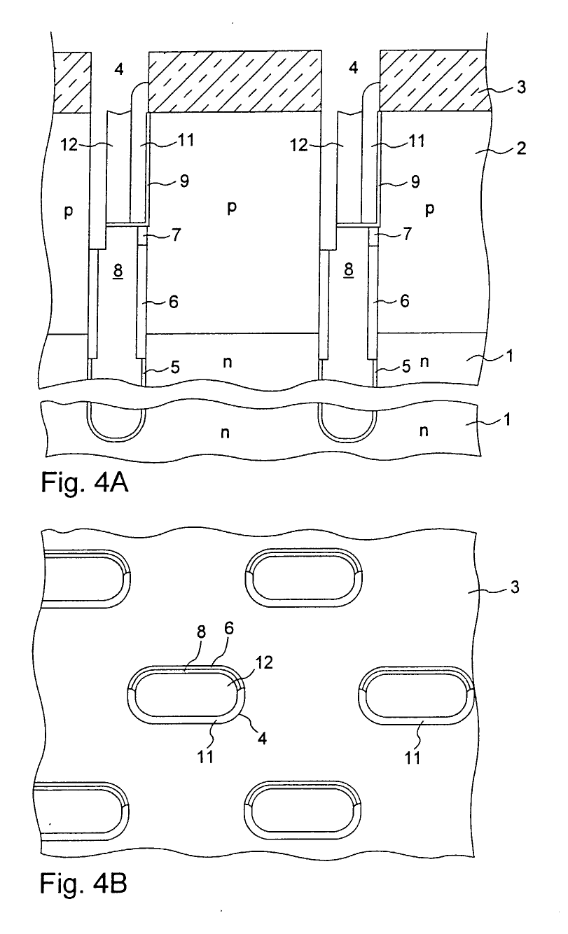

The p⁺-doped polycrystalline silicon 10 (or alternatively the undoped polycrystalline silicon 11) is then etched selectively. The thermal silicon dioxide layer 9 uncovered by this etching is etched back, and the region of the layer 7 made of amorphous silicon that is uncovered as a result is likewise removed by etching. The structure shown in FIGS. 4A and 4B is thus obtained.

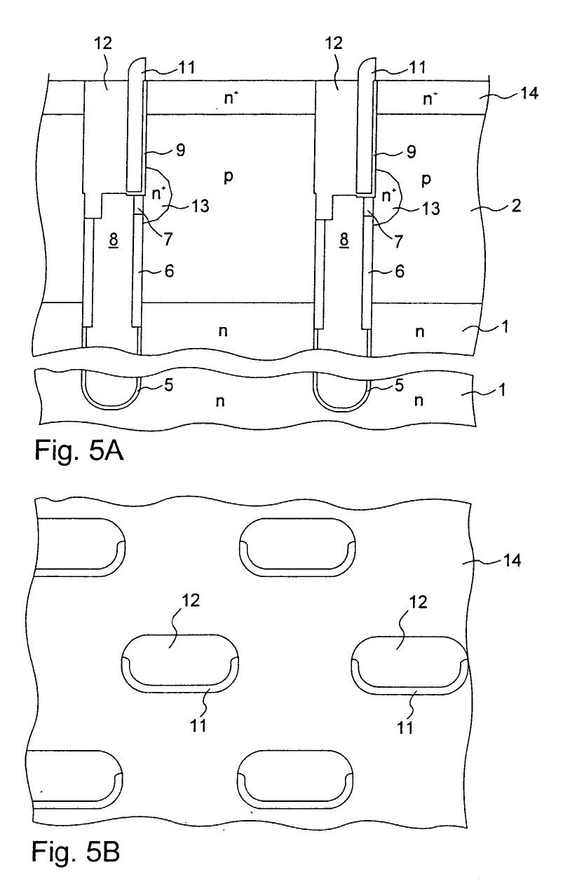

After depositing silicon dioxide (for example TEOS), chemical mechanical polishing (CMP), etching-back the silicon dioxide and removing the silicon nitride layer 3 by etching, a p-doped well and an n⁺-doped surface layer 14 are in each case produced by the implantation of, for example, boron for the p-doped well and arsenic for the n⁺-doped layer 14 and subsequent annealing. The structure shown in FIGS. 5A and 5B is thus present.

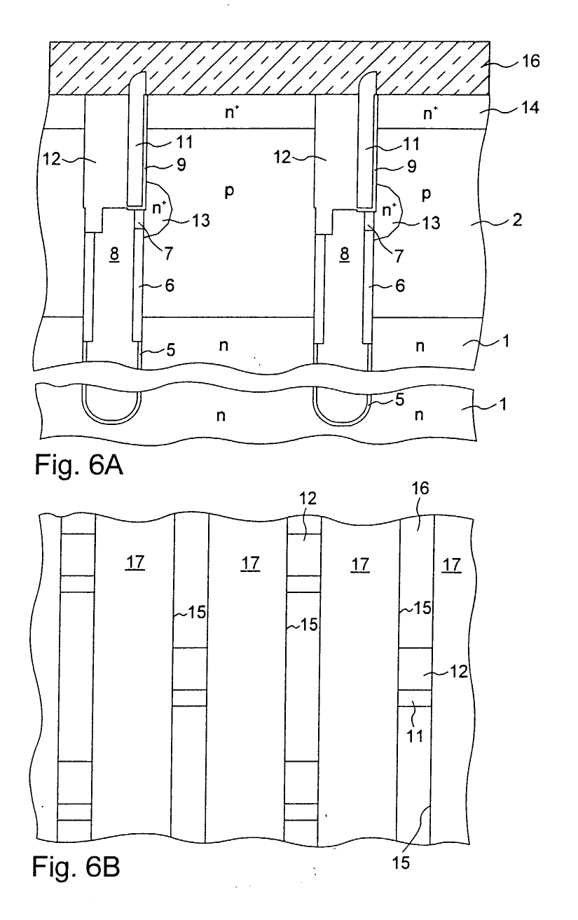

A silicon nitride layer 16 is then applied to the surface of the arrangement as shown in FIGS. 6A and 6B, and trenches 15 are then introduced using a photoresist and an etching technique. These trenches 15 in each case run in the edge region of the trenches 4, as is shown in FIG. 6B. These trenches 15 cannot be seen in FIG. 6A since they “intersect” the trenches 4 in front of or behind the plane of the drawing. The trenches 15 are filled with silicon dioxide (for example TEOS) 17 and are planarized by CMP (chemical mechanical polishing) and etching-back, The structure shown in FIGS. 6A and 6B is thus present.

After the removal of the silicon nitride layer 16, the undoped polycrystalline silicon 11 is etched selectively, and the silicon dioxide 17 is etched isotropically.

Afterward, according to the invention, by using ALD (atomic layer deposition), CVD (chemical vapor deposition) or a similar method, a layer 18 is deposited as a gate dielectric. The layer 18 is not produced by thermal oxidation. Silicon dioxide, silicon nitride, aluminum oxide or a similar material can be used for this layer 18. The layer 18 is used as a gate oxide and later insulates the selection transistor (in the upper region of the trench 4) from the storage capacitor (in the lower region of the trench 4).

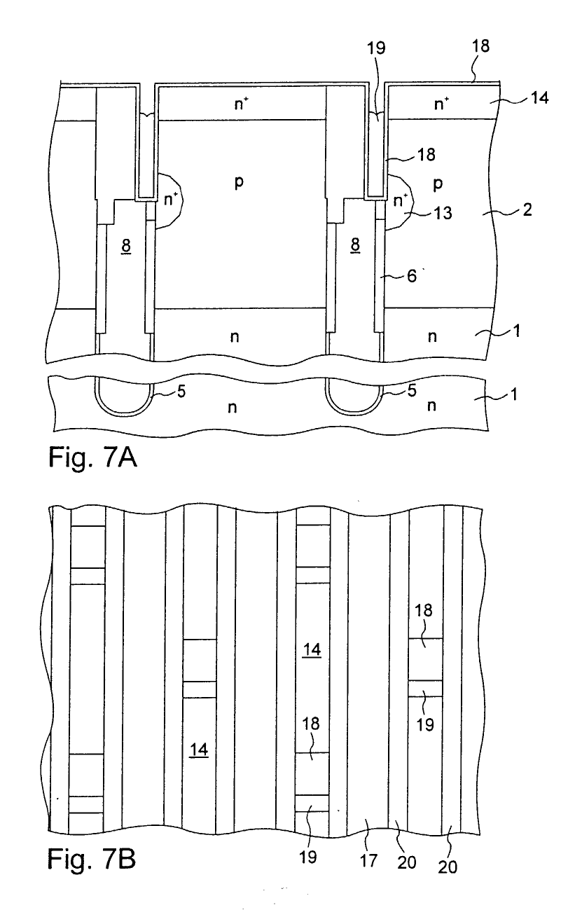

After the deposition of, for example, n-doped polycrystalline silicon 19 and tungsten layers 20 and anisotropic etching of these layers, the structure illustrated in FIGS. 7A and 7B is present (in FIG. 7B, the layer 18 provided on the silicon dioxide layer 17 and the n⁺-doped layer 14 have been omitted for the sake of better clarity).

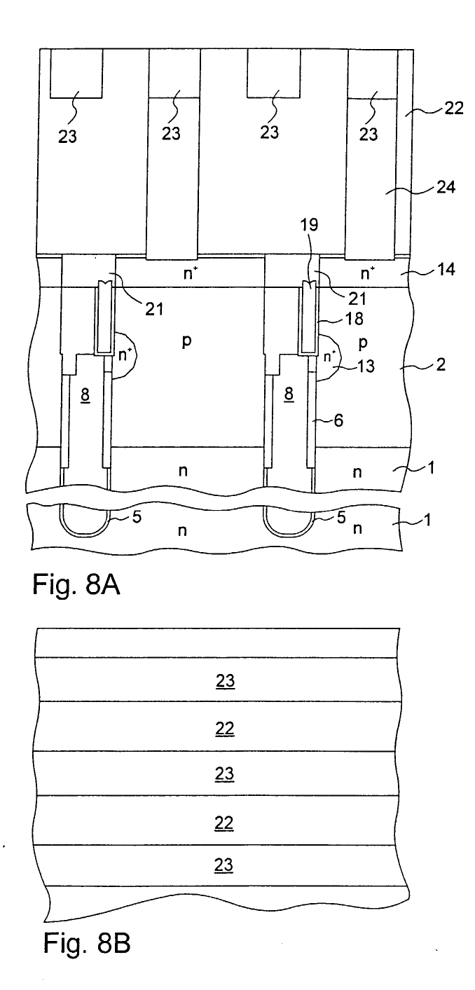

After the deposition of silicon nitride 21 in the region above the trenches 4 and etching-back this silicon nitride 21, a silicon dioxide layer 22 is applied, into which a metallization made of tungsten silicide 23 and doped polycrystalline silicon 24 is introduced in a customary manner. Thus, the structure shown in FIGS. 8A and 8B is finally present.

As can be seen from FIG. 8A, a vertical transistor includes the layer 14 as, for example, a source or drain, the silicon layer 2 as body, the layer 13 as the drain or the source, and the polysilicon 19 as gate electrode. The gate electrode is connected to a word line behind or in front of the plane of the drawing of FIG. 8A.

The storage capacitor has the polycrystalline silicon 8 as one electrode connected to the source or drain of the selection transistor, and the buried plate 1 as the other electrode at a fixed potential.

We claim:

1. A DRAM memory cell structure, comprising:
semiconductor material formed with a trench having a sidewall and a bottom region;
a storage capacitor provided in said bottom region of said trench;
a vertical transistor configured in said sidewall of said trench and configured above said storage capacitor; and
a deposited dielectric layer forming a first insulating layer isolating said transistor from said storage capacitor;
said dielectric layer also forming a second insulating layer serving as a gate insulator of said transistor.

2. The DRAM memory cell structure according to claim 1, wherein: said dielectric layer is made of a material selected from a group consisting of silicon dioxide, silicon nitride, and aluminum oxide.

3. The DRAM memory cell structure according to claim 1, wherein: said dielectric layer has a layer thickness of about 2 nm to about 20 nm.

4. A method for fabricating a DRAM memory cell structure, the method which comprises:
providing the memory cell structure with:
semiconductor material formed with a trench having a sidewall and a bottom region,
a storage capacitor provided in the bottom region of the trench,
a vertical transistor configured in the sidewall of the trench and configured above the storage capacitor, and
a deposited dielectric layer forming a first insulating layer isolating the transistor from the storage capacitor,
the dielectric layer also forming a second insulating layer serving as a gate insulator of the transistor; and
fabricating the dielectric layer using a process selected from a group consisting of atomic layer deposition and chemical vapor deposition.
